(19) United States
(12) Patent Application Publication
(10) Pub. No.: US 2013/0154003 A1
(43) Pub. Date: Jun. 20, 2013

(54) ASYMMETRIC ANTI-HALO FIELD EFFECT TRANSISTOR

(71) Applicants: James W. Adkisson, Jericho, VT (US); Brent A. Anderson, Jericho, VT (US); Andres Bryant, Burlington, VT (US); Edward J. Nowak, Essex Junction, VT (US)

(72) Inventors: James W. Adkisson, Jericho, VT (US); Brent A. Anderson, Jericho, VT (US); Andres Bryant, Burlington, VT (US); Edward J. Nowak, Essex Junction, VT (US)

(73) Assignee: International Business Machines Corporation, Armonk, NY (US)

(21) Appl. No.: 13/329,440

(22) Filed: Dec. 19, 2011

(51) Int. Cl. H01L 29/78; H01L 21/336

(52) U.S. Cl. 257/347; 438/286; 257/E29.255; 257/E21.409

(57) ABSTRACT

A method of forming an integrated circuit structure implants a first compensating implant into a substrate. The method patterns a mask on the first compensating implant in the substrate. The mask includes an opening exposing a channel location of the substrate. The method implants a second compensating implant into the channel location of the substrate. The second compensating implant is made through the opening in the mask and at an angle that is offset from perpendicular to the top surface of the substrate. The second compensating implant is positioned closer to a first side of the channel location relative to an opposite second side of the channel location and the second compensating implant comprises a material having the same doping polarity as the semiconductor channel implant. Then, the method forms a gate conductor above the channel location of the substrate in the opening of the mask.

### BACKGROUND

The present invention relates to the manufacture of integrated circuit devices, and more specifically, to controlling threshold voltage of transistors by using a blanket short channel compensating implant combined with an angled long channel compensating implant (asymmetric implant) made through the mask used for the gate conductor.

In order to increase integrated circuit device performance, it is often desirable to lower the threshold voltage required to make transistors switch from one state to another state. Various implants are utilized in order to lower the threshold voltage of transistors. For example, one common implant is known as “halo” implant and is created by performing angled implants of dopant species to drive the impurity beneath the gate conductor stack of the transistor.

However, as the size of transistors is reduced and as the density and pitch of transistors is increased, conventional halo masks can allow the angled implants to cause the compensating material to reach the source/drain regions of adjacent devices.

### SUMMARY

An exemplary method of forming an integrated circuit structure herein implants a first compensating implant into a substrate. The method patterns a mask on the first compensating implant in the substrate. The mask includes an opening exposing a channel location of the substrate. The method implants a second compensating implant into the channel location of the substrate. The second compensating implant is made through the opening in the mask and at an angle that is offset from perpendicular to the top surface of the substrate. The second compensating implant is positioned closer to a first side of the channel location relative to an opposite second side of the channel location, and the second compensating implant comprises a material having the same doping polarity as the semiconductor channel implant. Then, the method forms a gate conductor above the channel location of the substrate in the opening of the mask. Next, the method removes the mask to leave the gate conductor standing on the channel location of the substrate. The method implants source and drain implants into source/drain regions of the substrate (that are adjacent to the channel location).

Another method of forming an integrated circuit structure herein implants a first compensating implant into a substrate. The method patterns a mask on the first compensating implant in the substrate. The mask includes an opening exposing a channel location of the substrate. The method implants a second compensating implant into the channel location of the substrate. The second compensating implant is made through the opening in the mask and at an angle that is offset from perpendicular to the top surface of the substrate. The second compensating implant is positioned closer to a first side of the channel location relative to an opposite second side of the channel location, and the second compensating implant comprises a material having the same doping polarity as the semiconductor channel implant.

Then, the method forms a gate conductor above the channel location of the substrate in the opening of the mask. Next, the method removes the mask to leave the gate conductor standing on the channel location of the substrate. The method can then implant source and drain extensions into source/drain regions of the substrate (that are adjacent to the channel location) using the gate conductor as an alignment device. Also, the method can form sidewall spacers on the gate conductor. The method implants source and drain implants into the source/drain regions of the substrate using the sidewall spacers as an alignment device.

A further method of forming an integrated circuit structure herein implants a first compensating implant into a substrate. After implanting the first compensating implant, the method patterns a mask on the first compensating implant in the substrate. The mask includes an opening exposing a channel location of the substrate. After patterning the mask, the method forms a gate insulator material on the mask and on the channel location of the substrate, and implants a second compensating implant into the channel location of the substrate. The second compensating implant is made through the opening in the mask and at an angle that is offset from perpendicular to the top surface of the substrate. The second compensating implant is positioned closer to a first side of the channel location relative to an opposite second side of the channel location, and the second compensating implant comprises a material having the same doping polarity as the semiconductor channel implant.

Then, after implanting the second compensating implant, the method forms a gate conductor on the channel location of the substrate in the opening of the mask. Next, after forming the gate conductor, the method removes the mask to leave the gate conductor standing on the channel location of the substrate. After removing the mask, the method can then implant source and drain extensions into source/drain regions of the substrate (that are adjacent to the channel location) using the gate conductor as an alignment device. Also, after the mask is removed, the method can form sidewall spacers on the gate conductor. After forming the sidewall spacers, the method implants source and drain implants into the source/drain regions of the substrate using the sidewall spacers as an alignment device.

An integrated circuit structure embodiment herein comprises a semiconductor channel implant extending into a substrate to a first depth, and a first compensating implant extending into the substrate to a second depth. The first depth is further from the top surface of the substrate relative to the second depth. The first compensating implant comprises a material having a different doping polarity than the semiconductor channel implant. Further, a gate insulator material is on a channel location of the substrate, and a second compensating implant is in the channel location of the substrate. The second compensating implant is positioned closer to a first side of the channel location relative to an opposite second side of the channel location. Further, the second compensating implant comprises a material having the same doping polarity as the semiconductor channel implant. A gate conductor is on the gate insulator material over the channel location of the substrate. Also, source and drain extensions are in source/drain regions of the substrate adjacent to the channel location, sidewall spacers are on the gate conductor, and source and drain implants are in the source/drain regions of the substrate.

### BRIEF DESCRIPTION OF THE DRAWINGS

The embodiments herein will be better understood from the following detailed description with reference to the drawings, which are not necessarily drawing to scale and in which:

FIG. 1 is a cross-sectional schematic diagram of an integrated circuit device according to embodiments herein;

FIG. 2 is a cross-sectional schematic diagram of an integrated circuit device according to embodiments herein;

FIG. 3 is a cross-sectional schematic diagram of an integrated circuit device according to embodiments herein;

FIG. 4 is a cross-sectional schematic diagram of an integrated circuit device according to embodiments herein;

FIG. 5 is a cross-sectional schematic diagram of an integrated circuit device according to embodiments herein;

FIG. 6 is a cross-sectional schematic diagram of an integrated circuit device according to embodiments herein;

FIG. 7 is a cross-sectional schematic diagram of an integrated circuit device according to embodiments herein;

FIG. 8 is a cross-sectional schematic diagram of an integrated circuit device according to embodiments herein; and

FIG. 9 is a flow diagram of methods according to embodiments herein.

### DETAILED DESCRIPTION

As mentioned above, one common implant used to control threshold voltage of transistors is known as a “halo” implant and is created by performing angled implants of dopant species to drive the impurity beneath the gate conductor stack of the transistor. A conventional halo mask is shaped and sized so that it allows implanted materials to reach beneath the gate (and so that non-angled implants performed through the same mask opening will not reach under the gate). However, as devices are continually spaced closer to one another, conventional halo masks can allow the angled implants to cause the compensating material to reach the source/drain regions of adjacent devices.

Therefore embodiments herein provide an “anti-halo” compensating implant that is formed not from the outside of the gate inward (as is done with conventional halo implants); but from the inside of the gate region outward (and such is therefore referred to as an “anti” halo implant). As described in greater detail below, a first portion (short channel portion) of the compensating implant is formed as a blanket, uniform, non-angled implant. Subsequently, an additional amount of the compensating implant (long channel portion) is made at an angle through a mask opening before the gate conductor is formed (making the implant asymmetric). The mask that is utilized is the same mask used to damascene pattern the gate conductor (which avoids an additional masking step).

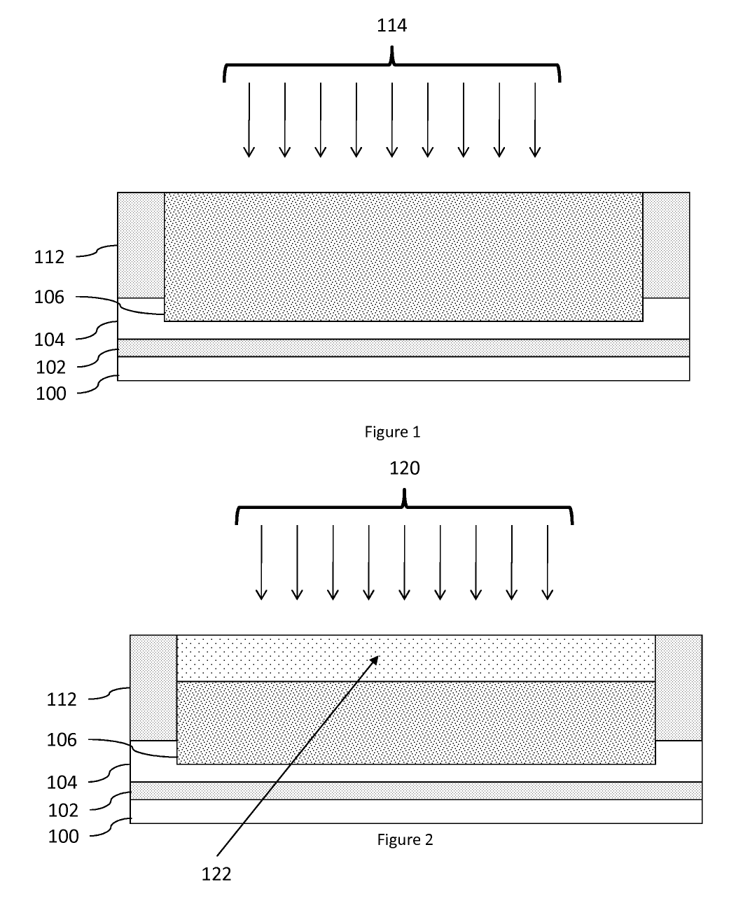

As shown generally in FIGS. 1-7, transistor structures are formed by depositing or implanting impurities into a substrate to form at least one semiconductor channel region 136, bordered by shallow trench isolation regions below the top (upper) surface of the substrate.

Specifically, as shown in FIG. 1, the substrate can comprise a uniform material or can be a multi-layer or laminated material, and a silicon-on-insulator (SOI) is used in the examples herein. This substrate includes an underlying silicon layer 100, a buried oxide layer 102, and an overlying silicon layer 104. The buried oxide layer 102 serves to insulate the structures formed in the silicon layer 104 from anything that may be subsequently connected to the lower silicon layer 100. For ease of reference herein, the entire substrate 100, 102, 104 is sometimes referred to herein as the “substrate 104.”

The upper layer 104 of the substrate can comprise any material appropriate for the given purpose (whether now known or developed in the future) and can comprise, for example, Si, SiC, SiGe, SiGeC, other III-V or II-VI compound semiconductors, or organic semiconductor structures, etc. If the upper layer 104 of the substrate is not intrinsically a semiconductor, the methods herein can implant 114 a semiconductor impurity 106 into the substrate 104 to a first depth. The implant shown by arrows 114 in FIG. 1 is uniformly made to all areas of the upper layer 104 of the substrate that will be utilized for a certain type of transistor. For purposes herein, a “semiconductor” is a material or structure that allows the material to sometimes be a conductor and sometimes be an insulator, based on electron and hole carrier concentration. As used herein, “implantation processes” can take any appropriate form (whether now known or developed in the future) and can comprise, for example, ion implantation, etc.

The method forms shallow trench isolation regions 112 into the substrate 104. The “shallow trench isolation” (STI) structures 112 are well-known to those ordinarily skilled in the art and are generally formed by patterning openings/trenches within the substrate 104 and growing or filling the openings with a highly insulating material (this allows different active areas of the substrate 104 to be electrically isolated from one another).

Within a transistor, the semiconductor 106 (or channel region 136) is positioned between a conductive “source” region 174 and a similarly conductive “drain” region 176 and when the semiconductor 106 is in a conductive state, the semiconductor 106 allows electrical current to flow between the source 174 and drain 176. A gate 152 is a conductive element that is electrically separated from the semiconductor 106 by a gate oxide 132 (which is an insulator) and current/voltage within the gate 152 changes the conductivity of the channel region 136 of the transistor.

A positive-type transistor “P-type transistor” uses impurities such as boron, aluminum or gallium, etc., within the semiconductor 106 (to create deficiencies of valence electrons) as a semiconductor region. Similarly, an “N-type transistor” is a negative-type transistor that uses impurities such as antimony, arsenic or phosphorous, etc., within the semiconductor 106 (to create excessive valence electrons).

In FIG. 2, embodiments herein implant an arbitrarily named “first” compensating implant 122 into the substrate 104 (shown by arrows 120) to a second depth to form the first compensating implant 122 region. The implant of impurities shown by arrows 120 in FIG. 2 is uniformly made to all areas of the upper layer 104 of the substrate that will be utilized for a certain type of transistor. Thus, the first compensating implant 122 is uniform at least between the shallow trench isolation regions 112. Further, as shown in the drawings, the “first” depth of the semiconductor region implant 106 is deeper than the “second” depth of the first compensating implant 122. This is especially true if the upper portion of the substrate 104 comprises an intrinsic semiconductor (where the entire upper portion of the substrate 104 is a semiconductor). In other words, the first depth is further from the top surface of the substrate 104 when compared to (relative to) the distance the second depth extends from the top surface of the substrate 104.

The first compensating implant 122 comprises a different material than the semiconductor channel implant 106. The first compensating implant 122 is also referred to herein as a “halo” implant because the first compensating implant 122 has an opposite doping polarity to the channel implant 106. For example, while the semiconductor channel implant 106 materials are discussed above, the first compensating implant 122 can be what is commonly referred to as a “short channel” implant, which is a doping species that is especially useful for transistors that have a short channel and can comprise, for example, for an N-type transistor, P-type transistor impurities such as boron, aluminum or gallium, etc. Conversely, for a P-type transistor, N-type transistor impurities that are especially useful for transistors that have a short channel, include antimony, arsenic or phosphorous, etc.

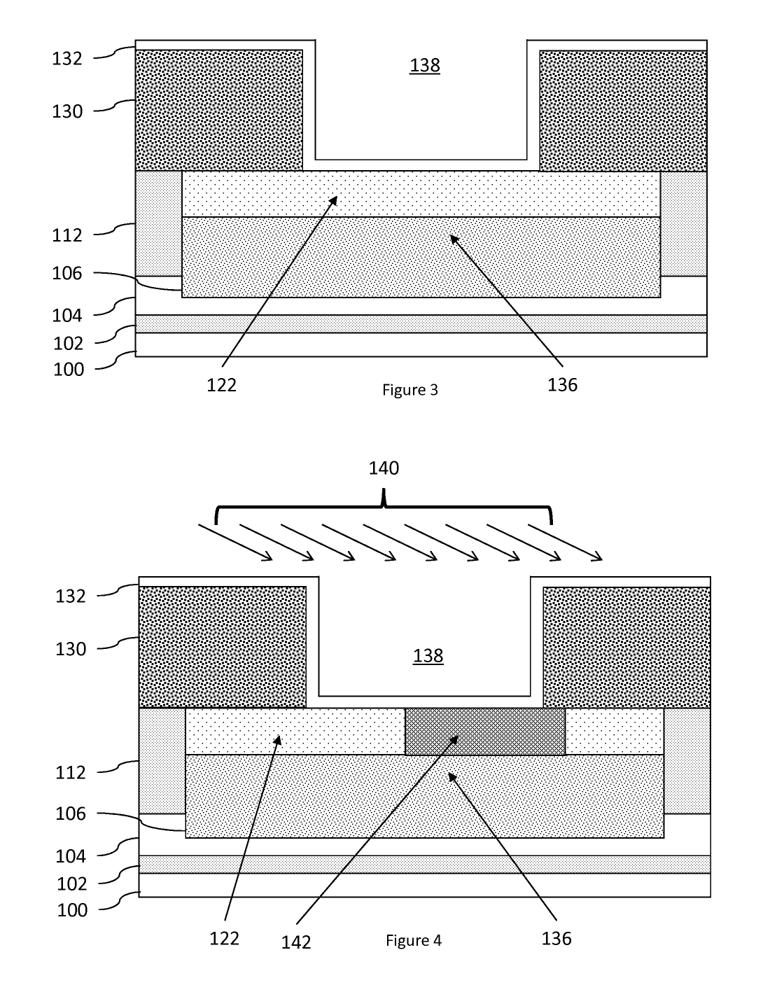

After implanting the first compensating implant 122, as shown in FIG. 3, the method patterns a mask 130 on the first compensating implant 122 in the substrate 104. The mask 130 includes an opening 138 exposing the channel location 136 of the semiconductor doped 106 regions of the substrate 104. The mask 130 can be formed of any suitable material, whether now known or developed in the future, such as a metal or organic mask 130.

When patterning any material herein, the material to be patterned can be grown or deposited in any known manner and a patterning layer (such as an organic photoresist) can be formed over the material. The patterning layer (resist) can be exposed to some pattern of light radiation (e.g., patterned exposure, laser exposure, etc.) provided in a light exposure pattern, and then the resist is developed using a chemical agent. This process changes the physical characteristics of the portion of the resist that was exposed to the light. Then one portion of the resist can be rinsed off, leaving the other portion of the resist to protect the material to be patterned. A material removal process is then performed (e.g., plasma etching, etc.) to remove the unprotected portions of the material to be patterned. The resist is subsequently removed to leave the underlying material patterned according to the light exposure pattern.

As also shown in FIG. 3, after patterning the mask 130, the method forms a gate insulator material 132 on the mask 130 and on the channel location 136 of the substrate 104. For purposes herein, an “insulator” is a relative term that means a material or structure that allows substantially less (<95%) electrical current to flow than does a “conductor.” The dielectrics (insulators) mentioned herein can, for example, be grown from either a dry oxygen ambient or steam and then patterned. Alternatively, the dielectrics herein may be formed from any of the many candidate high dielectric constant (high-k) materials, including but not limited to silicon nitride, silicon oxynitride, a gate dielectric stack of SiO₂ and Si₃N₄, and metal oxides like tantalum oxide. The thickness of dielectrics herein may vary contingent upon the required device performance.

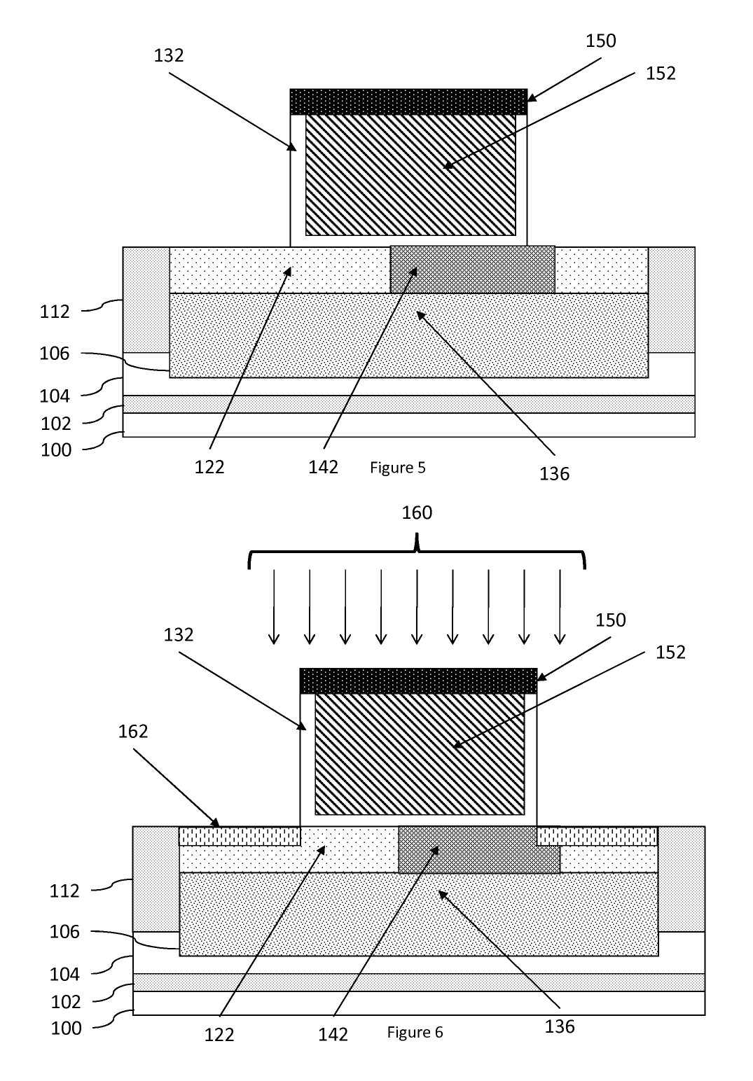

Once the mask 130 is in place (but potentially before or after the gate oxide 132 is formed); the methods herein implant an arbitrarily named “second” compensating implant (represented by arrows 140 in FIG. 4) of impurities into the channel location 136 of the substrate 104 to form what is referred to herein as the second compensating implant 142 region. The second compensating implant 142 is also referred to herein as an “anti-halo” implant because the second compensating implant 142 has an opposite doping polarity to the halo implant 122. Thus, the second compensating implant 142 has the same doping polarity as the semiconductor 106/channel 136. The second compensating implant 142 can be (but does not need to be) the same material as the semiconductor 106/channel 136. The first compensating implant 122 and the second compensating implant 142 alter the threshold voltage rollup characteristic of the integrated circuit structure.

The second compensating implant 142 is made through the opening 138 in the mask 130 and at an angle (e.g., 10°, 20°, 45°, 60°, 85°, etc.) that is offset from perpendicular) (90° to the top surface of the substrate 104 (as shown by arrows 140). Because the implant 140 is made at an angle (≠90°) the second compensating implant 142 will be asymmetric with respect to the opening 138. Therefore, the second compensating implant 142 is positioned closer to a first side (right side in the drawings) of the channel location 136 relative to an opposite second side (left side in the drawings) of the channel location 136, while the first compensating implant 122 is uniform across a width and length of the channel location 136. Further, while the drawings show the first and second compensating implants to be formed to the same depth within the substrate 104, those ordinarily skilled in the art would understand that the first and second compensating implants could be formed to different depths relative to each other.

The second compensating implant 142 comprises a different material than the first compensating implant 122 because the second compensating implant 142 has an opposite doping polarity to the halo implant 122, while the second compensating implant comprises a material having the same doping polarity as the semiconductor channel implant. For example, the second compensating implant 142 can be what is commonly referred to as a “long channel” implant, which is a doping species that is especially useful for transistors that have a long channel. Thus the second compensating implant 142 can comprise, for example, for an N-type transistor, N-type transistor impurities such as antimony, arsenic or phosphorous. Conversely, for a P-type transistor, the second compensating implant 142 can comprise P-type transistor impurities that are especially useful for transistors that have a long channel including, boron, aluminum or gallium, etc.

Then, after implanting the second compensating implant 142, the method forms a gate conductor 152 on the channel location 136 of the substrate 104 in the opening 138 of the mask 130. The conductors mentioned herein can be formed of any conductive material, such as polycrystalline silicon (polysilicon), amorphous silicon, a combination of amorphous silicon and polysilicon, and polysilicon-germanium, rendered conductive by the presence of a suitable dopant. Alternatively, the conductors herein may be one or more metals, such as tungsten, hafnium, tantalum, molybdenum, titanium, or nickel, or a metal silicide, any alloys of such metals, and may be deposited using physical vapor deposition, chemical vapor deposition, or any other technique known in the art.

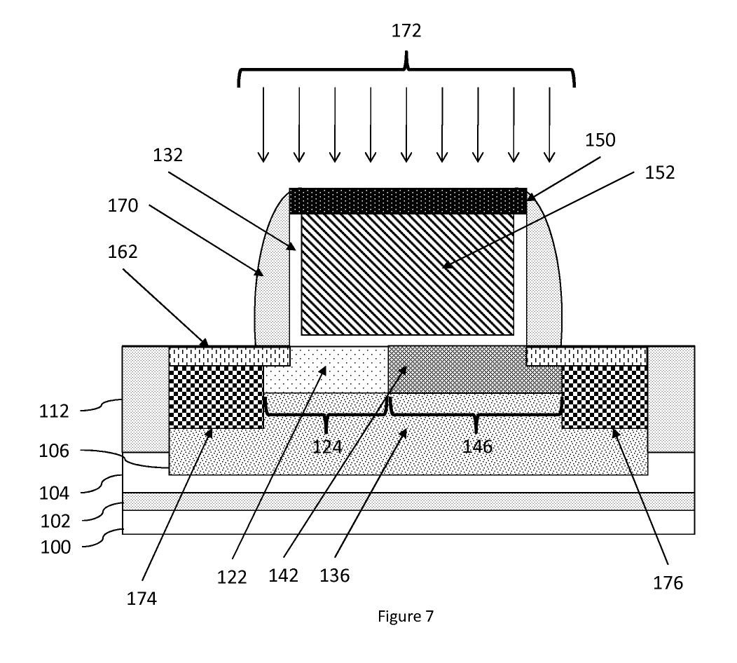

If desired, a gate cap 150 can be formed on the gate conductor 152 to protect the gate conductor 152 from subsequent processing. In any case, after forming the gate conductor 152, the method removes the mask 130 to leave the gate conductor 152 standing on the channel location 136 of the substrate 104 as shown in FIG. 5. After removing the mask 130, the method can then implant (shown by arrows 160 in FIG. 6) source and drain extensions 162 into source/drain regions of the substrate 104 (that are adjacent to the channel location 136) using the gate conductor 152 as an alignment device (self-aligned implantation).

Also, after the mask 130 is removed, the method can form sidewall spacers 170 on the gate conductor 152 as shown in FIG. 7. For purposes herein, “sidewall spacers” 170 are structures that are well-known to those ordinarily skilled in the art and are generally formed by depositing or growing a conformal insulating layer (such as any of the insulators mentioned above) and then performing a directional etching process (anisotropic) that etches material from horizontal surfaces at a greater rate than its removes material from vertical surfaces, thereby leaving insulating material along the vertical sidewalls of structures. This material left on the vertical sidewalls is referred to as sidewall spacers 170.

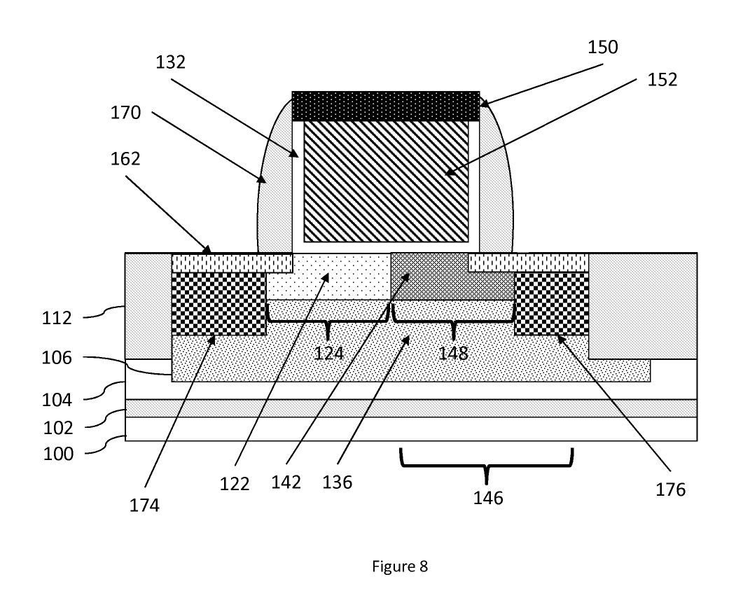

After forming the sidewall spacers 170, the method implants (as shown by arrows 172 in FIG. 7) source and drain implant impurities into the source/drain regions 174, 176 of the substrate 104 using the sidewall spacers 170 as an alignment device (self-aligned implantation). Further, because the angled anti-halo implant 140 is formed through the mask opening 138, the width (size) of the anti-halo implant 142 is automatically matched to the width (size) of the gate 152, as shown by the transistor in FIG. 8 which has a relatively more narrow gate 154 and a correspondingly relatively more narrow anti-halo implant 144 (relative to the width of the gate 152 and anti-halo implant 142 shown in FIG. 7). More specifically, because gate 154 is more narrow than wider gate 152, the width 148 (shown in FIG. 8) of the anti-halo implant 144 in FIG. 8 is more narrow than the width 146 (shown in both FIGS. 7 and 8 for comparison purposes) of the wider anti-halo implant 142. However, while the width 148 of the anti-halo implant is reduced in FIG. 8 (vs. the wider 146 anti-halo in FIG. 7), the width 124 of the halo implant 122 is consistent in both the narrower and wider gate examples of FIGS. 7 and 8. Therefore, the size of the opening 138 in the mask 130 controls the size of the second compensating implant 142 within the channel location 136 of the substrate 104, without affecting the size of the first compensating implant 122 within the channel location 136 of the substrate 104.

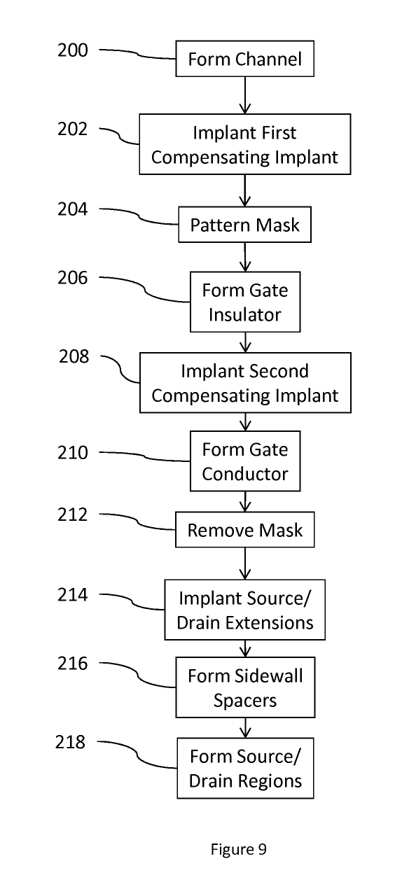

Exemplary methods of forming an integrated circuit structure herein are shown in flowchart form in FIG. 9. This flow begins in item 200, where such methods implant a semiconductor to form a channel implant in a substrate (to a first depth). In item 202, these processes implant a first compensating implant into the substrate to a second depth. The first depth is deeper than the second depth (the first depth is further from the top surface of the substrate relative to the second depth). The first compensating implant comprises a different material than the semiconductor channel implant.

After implanting the first compensating implant, these methods pattern a mask on the first compensating implant in the substrate (item 204). The mask includes an opening exposing a channel location of the substrate. After patterning the mask, as shown in item 206, the methods form a gate insulator material on the mask and on the channel location of the substrate. In item 208, such methods implant a second compensating implant into the channel location of the substrate. The second compensating implant is made through the opening in the mask and at an angle that is offset from perpendicular to the top surface of the substrate. The second compensating implant is asymmetric and positioned closer to a first side of the channel location relative to an opposite second side of the channel location, and the second compensating implant comprises a material having the same doping polarity as the semiconductor channel implant.

Then, after implanting the second compensating implant, the method forms a gate conductor on the channel location of the substrate in the opening of the mask (item 210). Next, in item 212, after forming the gate conductor, the method removes the mask to leave the gate conductor standing on the channel location of the substrate. After removing the mask, the method can then implant source and drain extensions into source/drain regions of the substrate (that are adjacent to the channel location) using the gate conductor as an alignment device in item 214. Also, after the mask is removed, the method can form sidewall spacers on the gate conductor in item 216. After forming the sidewall spacers, the method implants source and drain implants into the source/drain regions of the substrate in item 218 using the sidewall spacers as an alignment device.

Therefore, embodiments herein provide an “anti-halo” compensating implant that is formed not from the outside of the gate inward (as is done with conventional halo implants); but from the inside of the gate region outward. The compensating implant is made at an angle through the gate mask opening before the gate conductor is formed (making the implant asymmetric). This controls threshold voltage, yet avoids the problems that can occur with conventional halo masks, which can allow the conventional angled halo implants to reach the source/drain regions of adjacent devices. Further, the mask that is utilized is the same mask used to damascene pattern the gate conductor, which avoids an additional masking step.

The method as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

While only one or a limited number of transistors are illustrated in the drawings, those ordinarily skilled in the art would understand that many different types transistor could be simultaneously formed with the embodiment herein and the drawings are intended to show simultaneous formation of multiple different types of transistors; however, the drawings have been simplified to only show a limited number of transistors for clarity and to allow the reader to more easily recognize the different features illustrated. This is not intended to limit this disclosure because, as would be understood by those ordinarily skilled in the art, this disclosure is applicable to structures that include many of each type of transistor shown in the drawings.

In addition, terms such as “right”, “left”, “vertical”, “horizontal”, “top”, “bottom”, “upper”, “lower”, “under”, “below”, “underlying”, “over”, “overlying”, “parallel”, “perpendicular”, etc., used herein are understood to be relative locations as they are oriented and illustrated in the drawings (unless otherwise indicated). Terms such as “touching”, “on”, “in direct contact”, “abutting”, “directly adjacent to”, etc., mean that at least one element physically contacts another element (without other elements separating the described elements).

The terminology used herein is for the purpose of describing particular embodiments only and is not intended to be limiting of this disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A method of forming an integrated circuit structure, said method comprising:
implanting a first compensating implant into a substrate;
patterning a mask on said first compensating implant in said substrate, said mask including an opening exposing a channel location of said substrate;
implanting a second compensating implant into said channel location of said substrate through said opening at an angle that is offset from perpendicular to a top surface of said substrate, said second compensating implant being positioned closer to a first side of said channel location relative to an opposite second side of said channel location, and said second compensating implant comprising a material having the same doping polarity as said semiconductor channel implant;
forming a gate conductor above said channel location of said substrate in said opening of said mask;
removing said mask to leave said gate conductor standing on said channel location of said substrate; and
implanting source and drain implants into source/drain regions of said substrate adjacent to said channel location.

2. The method according to claim 1, said first compensating implant and said second compensating implant comprising different materials.

3. The method according to claim 1, said first compensating implant and said second compensating implant altering a threshold voltage rollup characteristic of said integrated circuit structure.

4. The method according to claim 1, said first compensating implant being uniform across a width and length of said channel location.

5. The method according to claim 1, further comprising forming shallow trench isolation regions into said substrate before implanting said first compensating implant.

6. The method according to claim 1, said substrate comprising a silicon-on-insulator substrate.

7. A method of forming an integrated circuit structure, said method comprising:
implanting a first compensating implant into a substrate;
patterning a mask on said first compensating implant in said substrate, said mask including an opening exposing a channel location of said substrate;
implanting a second compensating implant into said channel location of said substrate through said opening at an angle that is offset from perpendicular to a top surface of said substrate, said second compensating implant being positioned closer to a first side of said channel location relative to an opposite second side of said channel location, and said second compensating implant comprising a material having the same doping polarity as said semiconductor channel implant;
forming a gate conductor above said channel location of said substrate in said opening of said mask;
removing said mask to leave said gate conductor standing on said channel location of said substrate;
implanting source and drain extensions into source/drain regions of said substrate adjacent to said channel location using said gate conductor as an alignment device;
forming sidewall spacers on said gate conductor; and
implanting source and drain implants into said source/drain regions of said substrate using said sidewall spacers as an alignment device.

8. The method according to claim 7, said first compensating implant and said second compensating implant comprising different materials.

9. The method according to claim 7, said first compensating implant and said second compensating implant altering a threshold voltage rollup characteristic of said integrated circuit structure.

10. The method according to claim 7, said first compensating implant being uniform across a width and length of said channel location.

11. The method according to claim 7, further comprising forming shallow trench isolation regions into said substrate before implanting said first compensating implant.

12. The method according to claim 7, said substrate comprising a silicon-on-insulator substrate.

13. A method of forming an integrated circuit structure, said method comprising:
implanting a first compensating implant into a substrate;
after implanting said first compensating implant, patterning a mask on said first compensating implant in said substrate, said mask including an opening exposing a channel location of said substrate;
after patterning said mask, forming a gate insulator material on said mask and said channel location of said substrate;
after patterning said mask, implanting a second compensating implant into said channel location of said substrate through said opening at an angle that is offset from perpendicular to a top surface of said substrate, said second compensating implant being positioned closer to a first side of said channel location relative to an opposite second side of said channel location, and said second compensating implant comprising a material having the same doping polarity as said semiconductor channel implant;
after implanting said second compensating implant, forming a gate conductor on said channel location of said substrate in said opening of said mask;
after forming said gate conductor, removing said mask to leave said gate conductor standing on said channel location of said substrate, a size of said opening in said mask controls a size of said second compensating implant within said channel location of said substrate, without affecting a size of said first compensating implant within said channel location of said substrate;
after removing said mask, implanting source and drain extensions into source/drain regions of said substrate adjacent to said channel location using said gate conductor as an alignment device;
after removing said mask, forming sidewall spacers on said gate conductor; and
after forming said sidewall spacers, implanting source and drain implants into said source/drain regions of said substrate using said sidewall spacers as an alignment device.

14. The method according to claim 13, said first compensating implant and said second compensating implant comprising different materials.

15. The method according to claim 13, said first compensating implant and said second compensating implant altering a threshold voltage rollup characteristic of said integrated circuit structure.

16. The method according to claim 13, said first compensating implant being uniform across a width and length of said channel location.

17. The method according to claim 13, further comprising forming shallow trench isolation regions into said substrate before implanting said first compensating implant.

18. The method according to claim 13, said substrate comprising a silicon-on-insulator substrate.

19. An integrated circuit structure comprising:
a semiconductor channel implant extending into a substrate to a first depth;
a first compensating implant extending into said substrate to a second depth, said first depth being further from a top surface of said substrate relative to said second depth, said first compensating implant comprising a material having a different doping polarity than said semiconductor channel implant;
a gate insulator material on a channel location of said substrate;
a second compensating implant in said channel location of said substrate, said second compensating implant being positioned closer to a first side of said channel location relative to an opposite second side of said channel location, and said second compensating implant comprising a material having the same doping polarity as said semiconductor channel implant;
a gate conductor on said gate insulator material over said channel location of said substrate;
source and drain extensions in source/drain regions of said substrate adjacent to said channel location;
sidewall spacers on said gate conductor; and
source and drain implants in said source/drain regions of said substrate.

20. The integrated circuit structure according to claim 19, said first compensating implant and said second compensating implant comprising different materials.

21. The integrated circuit structure according to claim 19, said first compensating implant and said second compensating implant altering a threshold voltage rollup characteristic of said integrated circuit structure.

22. The integrated circuit structure according to claim 19, said first compensating implant being uniform across a width and length of said channel location.

23. The integrated circuit structure according to claim 19, further comprising shallow trench isolation regions in said substrate.

24. The integrated circuit structure according to claim 19, said substrate comprising a silicon-on-insulator substrate.
